(19) United States
(12) Patent Application Publication
(10) Pub. No.: US 2023/0096735 A1
(43) Pub. Date: Mar. 30, 2023

(54) ELECTROMAGNETIC RADIATION DETECTION SAFETY SEAT

(71) Applicant: V-HOLA Labs Ltd., Kfar Saba (IL)

(72) Inventors: Asaf TSIN, Kfar Saba (IL); Lior EMER, Petah Tikva (IL)

(73) Assignee: V-HOLA Labs Ltd., Kfar Saba (IL)

(21) Appl. No.: 17/802,450

(22) PCT Filed: Mar. 2, 2021
(86) PCT No.: PCT/IL2021/050232

§ 371 Date: Aug. 25, 2022

Related U.S. Application Data
(60) Provisional application No. 62/984,334, filed on Mar. 3, 2020.

(51) Int. Cl. G01R 29/12; G01R 33/02; B60N 2/26

(52) U.S. Cl. CPC G01R 29/12; G01R 33/02; B60N 2/26

(57) ABSTRACT

A child/infant safety seat comprising a computing device and at least one sensing unit connected with the computing device; wherein at least one of the at least one sensing unit is configured to detect electromagnetic (EM) and/or magnetic radiation and send measurements to the computing device; and wherein the computing device is configured to process the measurements, calculate the EM and/or the magnetic radiation detected by the at least one of the at least one sensing unit, and determine whether the detected EM and/or magnetic radiation is higher than at least one threshold value.

### CROSS-REFERENCE TO RELATED PATENT APPLICATIONS

This patent application claims priority from and is related to U.S. Provisional Patent Application Ser. No. 62/984,334, filed Mar. 3, 2020, this U.S. Provisional Patent Application incorporated by reference in its entirety herein.

### FIELD OF THE INVENTION

The present invention relates generally to electromagnetic radiation detection. More specifically, the present invention relates to a safety seat which detects electromagnetic radiation inside vehicles.

### BACKGROUND

Electric vehicles are the transportation means of the future. Electric and hybrid cars are already run in millions on roads all over the world, and electric airplanes and ships are under developments. These vehicles include many electronic components that may emit electromagnetic (EM) radiation that may accumulate, for example, in the passengers' cabin. Such a radiation, if above a certain level may be harmful, thus should be at least mapped and optionally also dealt with.

Accordingly, there is a need for a system and a method for detecting harmful radiation levels at a safety seat mounted inside vehicles.

### SUMMARY

According to an aspect of the present invention there is provided a child/infant safety seat, comprising: a computing device; and at least one sensing unit connected with the computing device; wherein at least one of the at least one sensing unit is configured to detect electromagnetic (EM) and/or magnetic radiation and send measurements to the computing device; and wherein the computing device is configured to process the measurements, calculate the EM and/or the magnetic radiation detected by the at least one of the at least one sensing unit, and determine whether the detected EM and/or magnetic radiation is higher than at least one threshold value.

At least one of the sensing units may comprise three EM sensors, assembled orthogonal to each other, each may be configured to measure EM field in a specific direction.

At least one of the sensing units may comprise a single EM sensor which may be configured to measure a 3D EM field.

At least one of the sensing units may comprise at least one of: a single EM sensor which may be configured to measure an EM field; and a single magnetic sensor which may be configured to measure magnetic flux density.

The at least one threshold value may be determined based on at least one of:

regulatory requirements and manufacturers' decision.

The computing device may further be configured to communicate with an In-Vehicle-Infotainment (IVI) for displaying at least one of: measurements and alerts.

The computing device may further be configured to communicate with a Telecommunication Unit (TCU) for displaying at least one of: measurements and alerts.

The computing device may further be configured to communicate with a User Communication Device (UCD) for displaying at least one of: measurements and alerts.

The computing device may further be configured to communicate with a remote server or a cloud for saving data related to the detected EM and/or magnetic radiation. According to another aspect of the present invention there is provided a method of detecting an electromagnetic (EM) and/or magnetic radiation at a child/infant safety seat, comprising: continuously measuring, by at least one sensing unit comprised in the child/infant safety seat, EM and/or magnetic radiation and sending the measurements to a computing device; processing, by the computing device, the measurements; calculating, by the computing device, the EM and/or magnetic radiation detected by at least one of the at least one sensing unit; and determining, by the computing device, whether the detected EM and/or magnetic radiation is higher than at least one threshold value.

The method of claim 10, wherein the at least one sensing unit comprises three EM sensors, assembled orthogonal to each other, each configured to measure EM field in a specific direction.

At least one of the sensing units may comprise three EM sensors, assembled orthogonal to each other, each may be configured to measure EM field in a specific direction.

At least one of the sensing units may comprise a single EM sensor which may be configured to measure a 3D EM field.

At least one of the sensing units may comprise at least one of: a single EM sensor which may be configured to measure an EM field; and a single magnetic sensor which may be configured to measure magnetic flux density.

The at least one threshold value may be determined based on at least one of:

regulatory requirements and manufacturers' decision.

The method may further comprise communicating, by the computing device, with an In-Vehicle-Infotainment (IVI) for displaying at least one of: measurements and alerts.

The method may further comprise communicating, by the computing device, with a Telecommunication Unit (TCU) for displaying at least one of: measurements and alerts. The method may further comprise communicating, by the computing device, with a User Communication Device (UCD) for displaying at least one of: measurements and alerts.

The method may further comprise communicating, by the computing device, with a remote server or a cloud for saving data related to the detected EM and/or magnetic radiation.

### BRIEF DESCRIPTION OF THE DRAWINGS

For better understanding of the invention and to show how the same may be carried into effect, reference will now be made, purely by way of example, to the accompanying drawings.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 shows a block diagram depicting a computing device, which may be included within a system for EM radiation detection, according to embodiments of the present zo invention;

FIG. 2 shows a block diagram of a system for detecting EM radiation at a safety seat, according to embodiments of the present invention;

FIG. 3 shows a flowchart of an exemplary method of electromagnetic (EM) radiation detection, according to embodiments of the present invention;

FIG. 4 shows a flowchart of another exemplary method of electromagnetic (EM) radiation detection, according to embodiments of the present invention; and

FIG. 5 shows exemplary safety seats.

### DETAILED DESCRIPTION OF PREFERRED EMBODIMENTS

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is applicable to other embodiments or of being practiced or carried out in various ways. Also, it is to be understood that the phraseology and terminology employed herein is for the purpose of description and should not be regarded as limiting.

One skilled in the art will realize the invention may be embodied in other specific forms without departing from the spirit or essential characteristics thereof. The foregoing embodiments are therefore to be considered in all respects of the invention described herein illustrative rather than limiting. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,”“establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term set when used herein can include one or more items. Unless explicitly stated, the method embodiments described herein are not constrained to a particular order or sequence.

Embodiments of the present invention disclose a method and a system for detection of EM radiation in an area of interest at a safety seat mounted in a vehicle. Such area of interest may be near the head, the center of the body, at the bottom and the like. The origin of the EM radiation may be from components included in the vehicle (e.g., an electric or hybrid vehicle). Such components may include, for example, the vehicle's electric motor, the vehicle's battery, the vehicle's electric wires, the vehicle's computer, the vehicle's power inventers, the vehicle's relay switches, the vehicle's radiofrequency (RF) components, Autonomous vehicle's processor, integrated or standalone (after market) product, and the like.

As used herein, a “vehicle” may be any form of transportation that includes one or more EM radiating components. For example, a vehicle maybe, an electric car, a hybrid car, an electric/hybrid bus, an electric/hybrid train, an electric/hybrid ship, an electric/hybrid airplane and the like. Moreover, the safety seat of the present invention may also detect radiation in a regular vehicle.

As used herein, an “EM radiation” may refer to the entire EM spectrum. More specifically, the EM radiation may refer to several more specific spectrums, for example, ultraviolet (UV) 3-30 PHz, infrared (IR) 300 GHz-3 PHz, spectrums included in the radiofrequency (RF) spectrum (3 Hz-300 GHz), such as extremely low frequency (ELF) 3-30 Hz, supper low frequency (SLF) 30-300 Hz. ultra-low frequency (ULF) 300-3 KHz, RF broadcasting bands 3 KHz-300 GHz, 500 MHz-6 GHz and the like. As known in the art, the higher the frequency the lower is the hazardous impact of the radiation on a subject. It will be appreciated that the term “EM radiation” may also refer to a magnetic radiation or magnetic flux density.

As used herein, a “radiating component” may be any component of a vehicle that radiates an EM radiation (at any spectrum). Some example so for radiating components radiating EM radiation at the ELF may include: the vehicle's electric motor, the vehicle's battery, the vehicle's electric wires, at least one of the vehicle's computers (e.g., an HPC architecture of electrical vehicles) , the vehicle's power inventers, the vehicle's relay switches and the like. Additional example, for radiating components radiating EM radiation at the wireless RF range, may include the vehicle's Bluetooth communication device, a GPS antenna, cellular radio module, Wi-Fi radio module and the like.

As used herein, an “area of interest” may include any area, volume, and place in the safety seat that may be affected from the presence of EM radiation above a certain level. For example, the area of interest may include the child's/infant's head area, legs area or any other area.

As used herein, a “child” may include an infant.

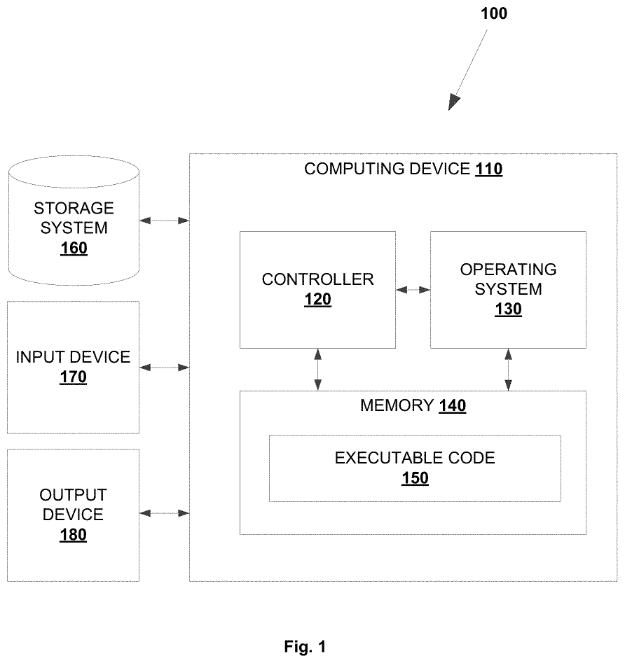

Reference is now made to FIG. 1, which is a block diagram 100 depicting a computing device, which may be included within a system for EM radiation detection, according to embodiments of the present invention. A computing device, such as device 110 may be included in the safety seat. In some embodiments more than one computing device 110 may be included in the safety seat.

Computing device 110 may include a controller 120 that may be, for example, a central processing unit (CPU) processor, a chip or any suitable computing or computational device, an operating system 130, a memory 140, executable code 150, a storage system 160, input devices 170 and output devices 180. Controller 120 (or one or more controllers or processors, possibly across multiple units or devices) may be configured to carry out methods described herein, and/or to execute or act as the various modules, units, etc. More than one computing device 110 may be included in, and one or more computing devices 110 may act as the components of, a system according to embodiments of the present invention.

Operating system 130 may be or may include any code segment (e.g., one similar to executable code 120 described herein) designed and/or configured to perform tasks involving coordination, scheduling, arbitration, supervising, controlling or otherwise managing operation of computing device 110, for example, scheduling execution of software programs or tasks or enabling software programs or other modules or units to communicate. Operating system 130 may be a commercial operating system. It will be noted that an operating system 130 may be an optional component, e.g., in some embodiments, a system may include a computing device that does not require or include an operating system 130. Memory 140 may be or may include, for example, a Random Access Memory (RAM), a read only memory (ROM), a Dynamic RAM (DRAM), a Synchronous DRAM (SD RAM), a double data rate (DDR) memory chip, a Flash memory, a volatile memory, a non volatile memory, a cache memory, a buffer, a short term memory unit, a long term memory unit, or other suitable memory units or storage units. Memory 140 may be or may include a plurality of, possibly different memory units. Memory 140 may be a computer or processor non -transitory readable medium, or a computer non-transitory storage medium, e.g., a RAM. In one embodiment, a non-transitory storage medium such as memory 140, a hard disk drive, another storage device, etc. may store instructions or code which when executed by a processor may cause the processor to carry out methods as described herein.

Executable code 150 may be any executable code, e.g., an application, a program, a process, task or script. Executable code 150 may be executed by controller 120 possibly under control of operating system 130. For example, executable code 150 may be an application that may conduct safety seat electromagnetic (EM) radiation detection as further described herein. Although, for the sake of clarity, a single item of executable code 150 is shown in FIG. 1, a system according to embodiments of the present invention may include a plurality of executable code segments similar to executable code 150 that may be loaded into memory 140 and cause controller 120 to carry out methods described herein.

Storage system 160 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) device or other suitable removable and/or fixed storage unit. For example, parameters of the vehicle, (virtual) meshing of the vehicle, the location of EM sensing units and/or the locations of radiating components may be stored in storage system 160 and may be loaded from storage system 160 into memory 140 where it may be processed by controller 120. In some embodiments, some of the components shown in FIG. 1 may be omitted. For example, memory 140 may be a non-volatile memory having the storage capacity of storage system 160. Accordingly, although shown as a separate component, storage system 160 may be embedded or included in memory 140. In some embodiments, storage system 160 may be a cloud base storage system.

Input devices 170 may be or may include any suitable input devices, components or systems, e.g., a detachable keyboard or keypad, a mouse and the like. Output devices 180 may include one or more (possibly detachable) displays or monitors, speakers and/or any other suitable output devices. Any applicable input/output (I/O) devices may be connected to computing device 110 as shown by blocks 170 and 180. For example, a wired or wireless network interface card (NIC), a universal serial bus (USB) device or external hard drive may be included in input devices 170 and/or output devices 180. It will be recognized that any suitable number of input devices 170 and output device 180 may be operatively connected to computing device 110 as shown by blocks 170 and 180.

A system according to embodiments of the present invention may include components such as, but not limited to, a plurality of central processing units (CPU) or any other suitable multi-purpose or specific processors or controllers (e.g., controllers similar to controller 120), a plurality of input units, a plurality of output units, a plurality of memory units, and a plurality of storage units.

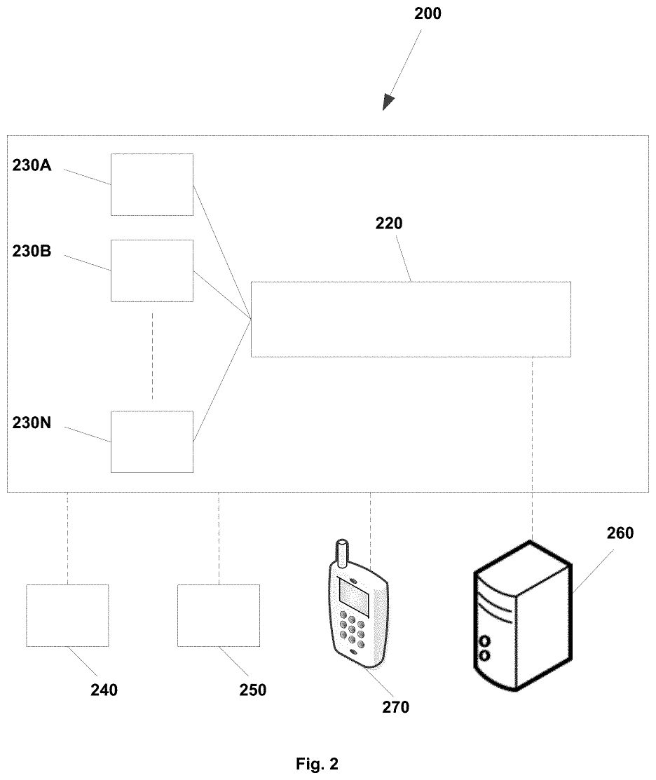

Reference is now made to FIG. 2, which is a block diagram of a system for detecting EM radiation at a safety seat according to embodiments of the present invention. A system such as system 200 may include a computing device 220 communicating with one or more EM sensing units 230A-230N. As should be understood by one skilled in the art the three sensing units illustrated in FIG. 2 are given as an example only and any number of EM sensing units, including one, can be included in the invention. In some embodiments, EM sensing units 230A-230N may communicate with computing device 220 via either wired or wireless communication using any known protocol (e.g., LAN, Bluetooth and the like).

In some embodiments, EM sensing units 230A-230N may include any sensing unit configured to detect an emission vector of an EM field generated by a component of the vehicle. In some embodiments, units 230A-230N may each include a single EM sensor configured to measure a 3D EM field (e.g., a magnetic field). In some embodiments, units 230A-230N may each include 3 EM sensors, each configured to measure an EM field (e.g., magnetic field) in a single direction. In such embodiments, the EM sensors may be assembled orthogonal to each other, each configured to measure EM field (e.g., a magnetic field) in a specific direction orthogonal to the direction of the field measured by the two other EM sensors. For example, the sensors may be Anisotropic Magnetoresistive (AMR) Sensors, such as, Honeywell HMC104, available from Honeywell, Hall Effect sensors, such as, DRV5053 available from Texas Instruments, Coil sensing unit and the like.

According to embodiments of the present invention, a unique Magnetic Field sensor may detect the range of 30 Hz to 30 KHz, while a different and unique EM sensor may detect the range of 500 MHz to 6 GHz.

In some embodiments, EM sensing units 230A-230N may be assembled at the closest locations to the surface of the seat on which the child is sitting. each radiating component. For example, a sensing unit 230A may be assembled behind the child's head. In another example, a sensing unit 230B may be assembled behind the child's back. In yet another example, a sensing unit 230C may be assembled behind the child's legs or arms.

According to embodiments of the present invention, the system 200 is intended to detect radiation emitted from various radiating components of the vehicle. Such components may be any component of the vehicle that radiates an EM radiation (at any spectrum). Some example of radiating components radiating EM radiation may include:

the vehicle's electric motor, the vehicle's battery, the vehicle's electric wires, at least one of the vehicle's computers, the vehicle's power inventers, the vehicle's relay switches, the vehicle's audio or multimedia system, a Bluetooth communication device, a GPS antenna, and the like.

According to embodiments of the present invention, the system 200 may further be connected with an In-Vehicle-Infotainment (IVI) 240, for example, for displaying alerts, measurements and the like; with the vehicle's Telecommunication Unit (TCU) 250 for transferring data to a remote server or a cloud 260; and/or with a User Communication Device (UCD) 270 for example, for displaying alerts, measurements and the like and transferring data to a remote server or a cloud 260.

It will be appreciated that the system 200 may be wirely connected with the vehicle for the purpose of, for example, transferring alerts, data and the like and/or receiving power. Alternatively, the system 200 may be wirelessly connected with the TCU 250 and/or the UCD 270 for the purpose of, for example, transferring alerts, data and the like. In such cases or the like, the system may use at least one battery (not shown) as a power source.

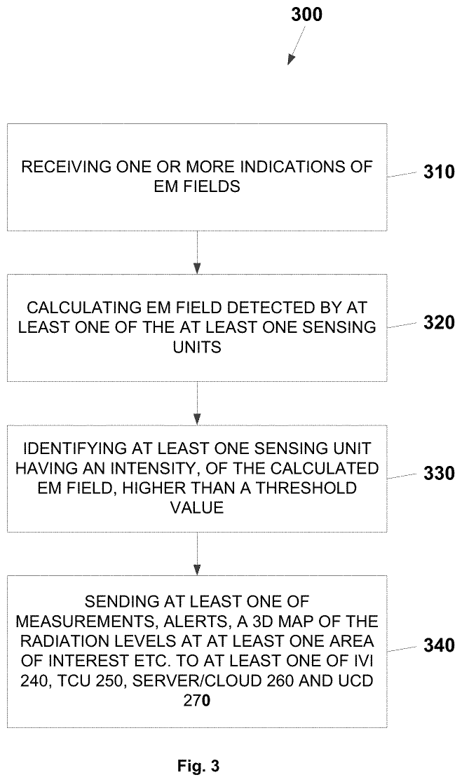

Reference is now made to FIG. 3 which is a flowchart 300 of an exemplary method of electromagnetic (EM) radiation detection to be executed by at least one processor (e.g., controller 120 of computing device 110) according to embodiments of the present invention. In step 310, the processor may receive one or more indications of EM fields generated, for example, by one or more radiating components. For example, controller 120 may receive from one or more EM sensing units 230A-230N the size and direction of the EM field detected due to operation of one or more of the vehicle's radiating components.

In some embodiments, controller 120 may be intended to calculate indications related to emission vectors of EM field based on received operation parameters, for example, by calculating the size and direction of the magnetic field measured at an examined location.

In some embodiments, receiving the one or more indications may be conducted at predetermined time intervals. For example, one or more indications may be received from at least one sensing unit 230A-230N or may be calculated every several seconds, for example, every 0.1, 0.5, 1, 2, 3, or 4 second. In some embodiments, the time interval may be determined such that it will not exceed the maximum allowed exposure time according to safety regulation (e.g., 6 minutes). In some embodiments, the longer the time of exposure the higher is the risk for harmful damage (either to a human, an animal or an electronic component). Accordingly, a maximum allowed exposure time is defined by the International Commission on Non -Ionizing Radiation Protection (ICNIRP). World Health Organization (WHO) instructions as well as regulatory bodies worldwide instructions derive from ICNRIP's recommendations. ICNIRP update its recommendations from time to time.

In step 320, the EM field is detected by at least one of the at least one sensing unit 230A-230N.

The EM field may be calculated using known in the art equations.

It will be appreciated that any equation for calculating radiation or radiation over time may be used.

The Exposure time is defined as the maximum time one is allowed to be exposed to a certain radiation without being harmed.

In step 330, at least one sensing unit, having an intensity of the calculated EM field, higher than one or more threshold values, may be identified. In some embodiments, the one or more threshold values may be determined based on at least one of: regulatory requirements, manufacturers' decision, fleet management decision and the like. In some embodiments, sensing units located at different areas of the safety seat may be identified using different threshold values. For example, different threshold values may be determined for EM filed near the head of the child and for EM filed near the legs of the child. For example, the threshold values near the head of the child may be determined based on regulation set by the International Commission on Non-Ionizing Radiation Protection (ICNIRP), the World Health Organization (WHO) instructions as well as regulatory bodies worldwide instructions derive from ICNRIP's recommendations. ICNIRP update its recommendations from time to time. In another example, the threshold levels/values may be determined based on or defined by EMC compliance for vehicles set by, for example, the manufacturer of the vehicle. The electromagnetic compatibility (EMC) is the ability of electrical equipment and systems to function acceptably in their electromagnetic environment.

In some embodiments, controller 120, may send to a user (e.g., via UCD 270) measurements and/or alerts that the levels of EM radiation in at least some location in the area of interest exceeded at least one threshold value. In some embodiments, the measurements and/or the alerts may be stored in the database or the cloud 260.

Therefore, in step 340, controller 120, may send at least one of measurements and alerts to at least one of IVI 240, TCU 250, remote server or cloud 260 and UCD 270.

It will be appreciated that step 340 is optional.

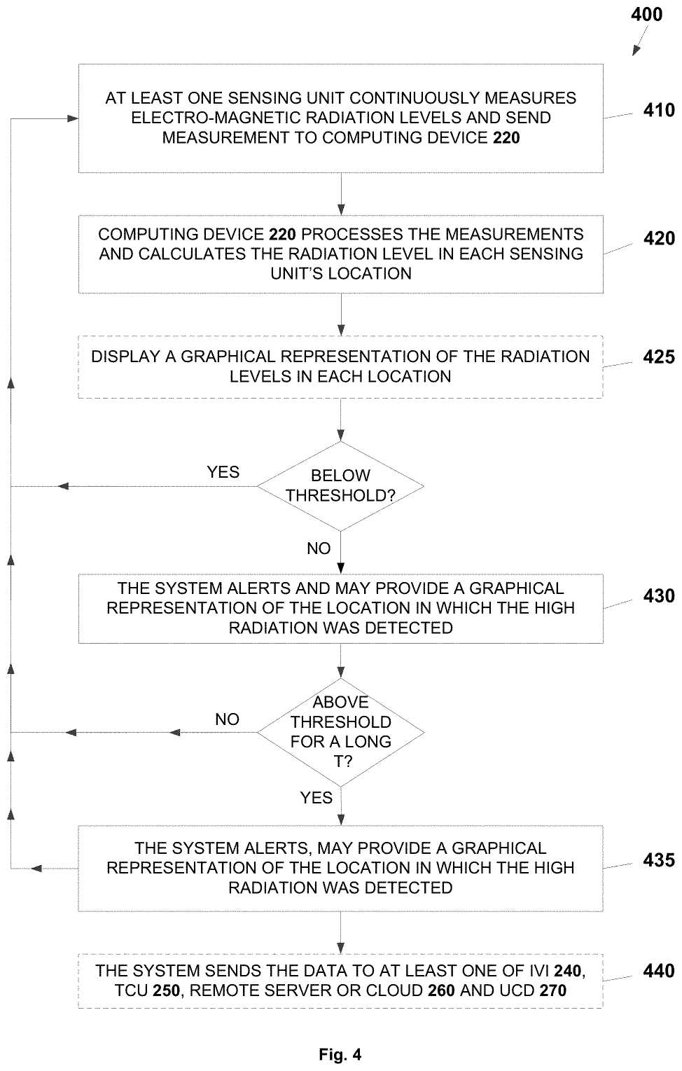

Reference is now made to FIG. 4 which is a flowchart 400 of another exemplary method of electromagnetic (EM) radiation detection to be executed by at least one processor (e.g., controller 120 of computing device 110) according to embodiments of the present invention.

In step 410, at least one sensing unit continuously (according to predetermined periods) measures electro-magnetic radiation levels and send measurement to computing device 220.

In step 420, the computing device 220 processes the measurements and calculates the radiation level in each sensing unit's location.

In step 425, the system may optionally display a graphical representation of the radiation levels in each location.

As long as the radiation levels are below the predetermined threshold, the process goes back to step 410.

If at least one radiation level is above threshold, in step 430, the system alerts and may provide a graphical representation of the location in which the high radiation was detected.

If at least one radiation level is above threshold for a long period of time, in step 435, the system alerts and may provide a graphical representation of the location in which the high radiation was detected. The process goes back to step 410.

According to embodiments of the present invention, step 435 may additionally be followed by step 440 in which the system may optionally send the data to at least one of IVI 240, TCU 250, remote server or cloud 260 and UCD 270. The data may include measured and/or calculated radiation levels over time, measurements, alerts etc.

It will be appreciated that the method of FIG. 4 may end before step 430 is performed or after step 430 is completed.

In such a case, step 430 may additionally be followed by step 440 in which the system may optionally send the data to at least one of IVI 240, TCU 250, remote server or cloud 260 and UCD 270. The data may include measured and/or calculated radiation levels over time, measurements, alerts etc.

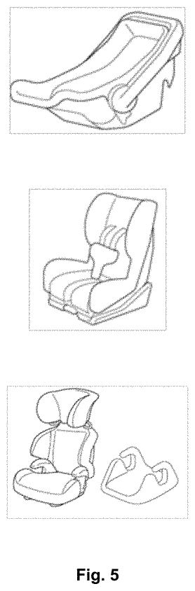

It will be appreciated that the system of the present invention may be installed in any safety seat, such as presented, for example, in FIG. 5. Examples of safety seats may be, but not limited to, an infant car seat, a rear-facing car seat, a convertible seat, an All-in-One seat, a combination seat, a child car seat, a booster seat or any other safety seat.

Therefore, a system and method according to some embodiments of the present invention may allow increasing the safety of children sitting in a safety seat, by detecting and alerting regarding exposure of harmful EM radiation.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

It will be appreciated by persons skilled in the art that the present invention is not limited to what has been particularly shown and described hereinabove. Rather the scope of the present invention is defined by the appended claims and includes combinations and sub-combinations of the various features described hereinabove as well as variations and modifications thereof which would occur to persons skilled in the art upon reading the foregoing description.

1. A child/infant safety seat, comprising:
a computing device; and
at least one sensing unit, assembled in the child/infant safety seat, connected with said computing device;
wherein at least one of said at least one sensing unit is configured to detect electromagnetic (EM) and/or magnetic radiation in the vicinity of the child/infant safety seat and send measurements to said computing device; and
wherein said computing device is configured to:
process said measurements,
calculate said EM and/or said magnetic radiation detected by said at least one of said at least one sensing unit,
send an alert to a user deviceif said detected EM and/or magnetic radiation is higher than at least one child-related threshold value, wherein said child-related threshold value is determined based on at least one of: regulatory requirements manufacturers' decision.

2. The safety seat of claim 1, wherein said at least one sensing unit comprises three EM sensors, assembled orthogonal to each other, each configured to measure EM field in a specific direction.

3. The safety seat of claim 1, wherein said at least one sensing unit comprises a single EM sensor configured to measure a 3D EM field.

4. The safety seat of claim 1, wherein said at least one sensing unit comprises at least one of: a single EM sensor configured to measure an EM field; and a single magnetic sensor configured to measure magnetic flux density.

5. (canceled)

6. The safety seat of claim 1, wherein said computing device is further configured to communicate with an In-Vehicle-Infotainment (IVI) for displaying at least one of:
measurements and alerts.

7. The safety seat of claim 1, wherein said computing device is further configured to communicate with a Telecommunication Unit (TCU) for displaying at least one of:
measurements and alerts.

8. The safety seat of claim 1, wherein said computing device is further configured to communicate with a User Communication Device (UCD) for displaying at least one of: measurements and alerts.

9. The safety seat of claim 1, wherein said computing device is further configured to communicate with a remote server or a cloud for saving data related to said detected EM and/or magnetic radiation.

10. A method of detecting an electromagnetic (EM) and/or magnetic radiation at a child/infant safety seat, comprising:
continuously measuring, by at least one sensing unit comprised in said child/infant safety seat, EM and/or magnetic radiation, in the vicinity of the child/infant safety seat, and sending said measurements to a computing device;
processing, by said computing device, said measurements;
calculating, by said computing device, said EM and/or magnetic radiation detected by at least one of said at least one sensing unit; and
sending, by said computing device, an alert to a user device if said detected EM and/or magnetic radiation is higher than at least one child-related threshold value, wherein said child-related threshold value is determined based on at least one of: regulatory requirements manufacturers' decision.

11. The method of claim 10, wherein said at least one sensing unit comprises three EM sensors, assembled orthogonal to each other, each configured to measure EM field in a specific direction.

12. The method of claim 10, wherein said at least one sensing unit comprises a single EM sensor configured to measure a 3D EM field.

13. The method of claim 10, wherein said at least one sensing unit comprises at least one of: a single EM sensor configured to measure an EM field and a single magnetic sensor configured to measure magnetic flux density.

14. (canceled)

15. The method of claim 10, further comprising communicating, by said computing device, with an In-Vehicle-Infotainment (IVI) for displaying at least one of:
measurements and alerts.

16. The method of claim 10, further comprising communicating, by said computing device, with a Telecommunication Unit (TCU) for displaying at least one of:
measurements and alerts.

17. The method of claim 10, further comprising communicating, by said computing device, with a User Communication Device (UCD) for displaying at least one of: measurements and alerts.

18. The method of claim 10, further comprising communicating, by said computing device, with a remote server or a cloud for saving data related to said detected EM and/or magnetic radiation.
